(19) United States
(12) Patent Application Publication
(10) Pub. No.: US 2011/0291692 A1
(43) Pub. Date: Dec. 1, 2011

(54) METHOD AND APPARATUS FOR INSPECTING SEMICONDUCTOR USING ABSORBED CURRENT IMAGE

(76) Inventors: Tohru Ando, Tokyo (JP); Masaaki Komori, Hitachinaka (JP); Takao Matsuura, Hitachi (JP)

(21) Appl. No.: 13/147,759

(22) PCT Filed: Jan. 20, 2010
(86) PCT No.: PCT/JP2010/000280

§ 371 Date: Aug. 3, 2011

(30) Foreign Application Priority Data
Feb. 6, 2009 (JP) 2009025493

(51) Int. Cl. G01R 31/26

(52) U.S. Cl. 324/762.01

(57) ABSTRACT

Provided is an apparatus for automatically detecting a failure position on a specified wiring line. The apparatus and a method for automatically detecting the failure position even on a long wiring line by applying a probe and an electron beam onto a sample and using an image of the current absorbed by the sample are provided. The apparatus obtains an absorbed current image, while laterally moving at right angle with the probe applied onto the sample, and based on the obtained absorbed current image, correction is performed by means of both an image shift and a stage. Countermeasures are taken, using a stage not having a sample rotating stage, against factors including a hardware factor of not moving at a correct angle, such as backlash, the wiring line is accurately and continuously displayed even when the apparatus moves to the ends of the long wiring line, and the failure position is detected, while the apparatus automatically reciprocates several times between the both ends of the wiring line.

### TECHNICAL FIELD

The present invention relates to semiconductor inspection methodology and apparatus, and more particularly to a method and apparatus for performing semiconductor inspection using an absorbed current flowing in a sample due to an electron beam of scanning electron microscope (SEM).

### BACKGROUND ART

In recent years, advances in miniaturization of 45-nm devices and semiconductor device result in the analysis of wiring failures or defects becoming not easy. In the wiring defect analysis, while laser light-used OBIRCH and emission microscopy are also effective, a scheme for observing an EBAC (Electron Beam Absorbed Current) image is effective, which determines a defect position using an electron beam's absorbed electron current in a sample. An example thereof is disclosed in Patent Literature 1.

A feature of this method is that defect positions are definitely determinable in a way corresponding to open-circuit defects, short-circuit defects and electrical resistance because of the fact that an absorbed current of the electron beam flows in multi-layered wiring lines and that the amount of such absorbed current of only an electrically conducted wire is directly converted into brightness that is visible to human eyes.

The EBAC image is to display an absorbed current flowing in the inside of a sample. Accordingly, in order to display the absorbed current, it is necessary to bring a probe (needle) into contact with the sample and then connect it to the amplifier.

### CITATION LIST

### Patent Literature

Patent Literature 1: JP-A-2002-343843

### SUMMARY OF INVENTION

### Technical Problem

The sample to be measured is a mat of long wiring lines or a via chain, a long one of which is about 4 mm. An image shift deflector cannot be used to perform image shift that is as long as 4 mm; so, in order to see the EVAC image of a long distance, it has been required, after having observed by needle contact, to raise the needle, separate it from the sample, move a stage, and perform the needle contact again. A pointed tip of a probe which is fine enough to enable direct contact with a wire is 100 nm, or more or less. Basically, this is because the probe can be bent accidentally when forcing the stage to move while retaining the needle in the contact state.

There is a case where defect positions are detectable even at a low magnification of about 400 times; however, in view of the fact that defects are gradually becoming less detectable due to miniaturization, it is required, in order to find a defect position from the EVAC image more accurately, to exactly detect a tiny brightness difference at a magnification of about twenty thousand times.

In order to detect the presence of a difference in an absorbed electron current, a viewing field becomes a width of 126 μm in the case of a display screen with a magnification of one-thousand times on a laterally long screen (640 by 480 dots). For example, to distinguish a 4-mm wiring line, it is needed to recognize 32 display screens at a time. This is a work operation with visual checking while further magnifying a location which seems to be a defect.

Also note that in the case of the magnification of twenty thousand times, the viewing field corresponding to one screen becomes equivalent to a width of 6.3 μm. This makes it necessary to sequentially observe 635 screens.

As apparent from the foregoing, it is necessary, even for a straight line with a length of several millimeters, to enlarge it up to a magnification of several tens of thousands; thus, it is a must for an observer to verify the above-stated huge display screen.

Additionally, as for observation image acquisition, there are problems which follow.

Image display using an absorbed current of electron beam is unable to cope with rapid scanning, such as a TV scan mode which raster-scans one screen by 20 msec. To display a correct image, scan of several seconds is required for one screen. To clarify a defect position more successfully, slow scan is deemed preferable; however, this results in an increase in length of a time taken for the analysis of an entirety.

Furthermore, it is required to drive the stage to travel a distance of 4 mm while at the same time maintaining the probe in the contact state. A relationship between the stage and the probe is as follows: the probe is above the moving stage; it is essential for them to move in a linked manner—even in such case, there is the possibility that the probe is accidentally bent by vibrations. In addition, when stopping the stage every time an image is acquired, the vibration load becomes greater, resulting in an unwanted increase in analysis time.

It is an object of this invention to realize, by taking into consideration the above-stated problems, a semiconductor inspection method and apparatus capable of definitely indicating defect positions of wiring lines with enhanced rapidity and increased accuracy.

### Solution to Problem

The semiconductor inspection method of this invention is arranged to move a stage while simultaneously letting a probe be in contact with a sample and perform defect observation of long wiring lines in an automated way to thereby ensure that the needle touching is no longer required every time the stage is moved. Although with this arrangement there is influence on vibrations applied to the probe, remedial action is taken by stage movement which is made less in damage including backlash.

It is also arranged to perform movement of a minimal distance with backlash removability at a slow stage speed and, in view of the fact that it largely moves from a screen at a time point at which the backlash of height was taken away, perform correction or “amendment” while simultaneously monitoring an on-screen image in such a manner that a wiring line comes at the center of a display screen. On the lateral side, movement is done until the backlash is removed. A correction method is such that the velocity of Y-axis is adjusted by a deviation amount of Y-axis from present speeds of X-axis and Y-axis and the brightness of an absorbed current.

Further, by utilizing the fact that the wiring line is linear, feedback from an image is performed to continue performing correction to a correct angle. That is to say, the correction is repeated at unit time intervals each being several tens of milliseconds whereby amendment is done to ensure that the wire comes at the center without performing any image shift, and a present deviation amount is amended by the image shift, thereby determining again the angle in such a way as to operate properly. Additionally, in this movement, when it is judged that the image shift amount is less, the table is daringly controlled to an extent that it goes excessively and is driven to move until the image shift becomes less in swing width.

In a case where the scan direction and the wiring line cross together orthogonally, control is provided in the scheme employed herein to force the scan direction and the wire to be in almost parallel with each other.

Regarding the stage movement also, let it be an “S”-like driven movement that lessens the acceleration in order to lessen vibrations applied to the probe.

In addition, in order to increase the scan speed, how to swing a primary electron beam is arranged to have a coverage corresponding not to an image display frame of the whole display screen but to a range with its size enough for the wire and its nearby portions to be contained therein in view of the fact that what is required here is to permit the wire per se to be visually displayed.

An example is that visualization is carried out within a range of ¼ the height of display screen (120 dots out of 480 dots). As it is necessary to continue displaying the wire during stage movement, when letting the screen height be ¼, it becomes a point to move at a correct angle while it is traveling a length of several millimeters. Consequently, by using the fact that the wire is a straight line, an arrangement is made for performing correction by the image shift in such a way that this wire always comes at a location close proximity to the center of the height of the display screen.

### ADVANTAGEOUS EFFECTS OF INVENTION

According to this invention, it is possible to realize a semiconductor inspection method, semiconductor inspection apparatus and semiconductor inspection apparatus capable of rapidly and accurately analyzing defect positions of wiring lines, thereby enabling user's usability of the apparatus to improve.

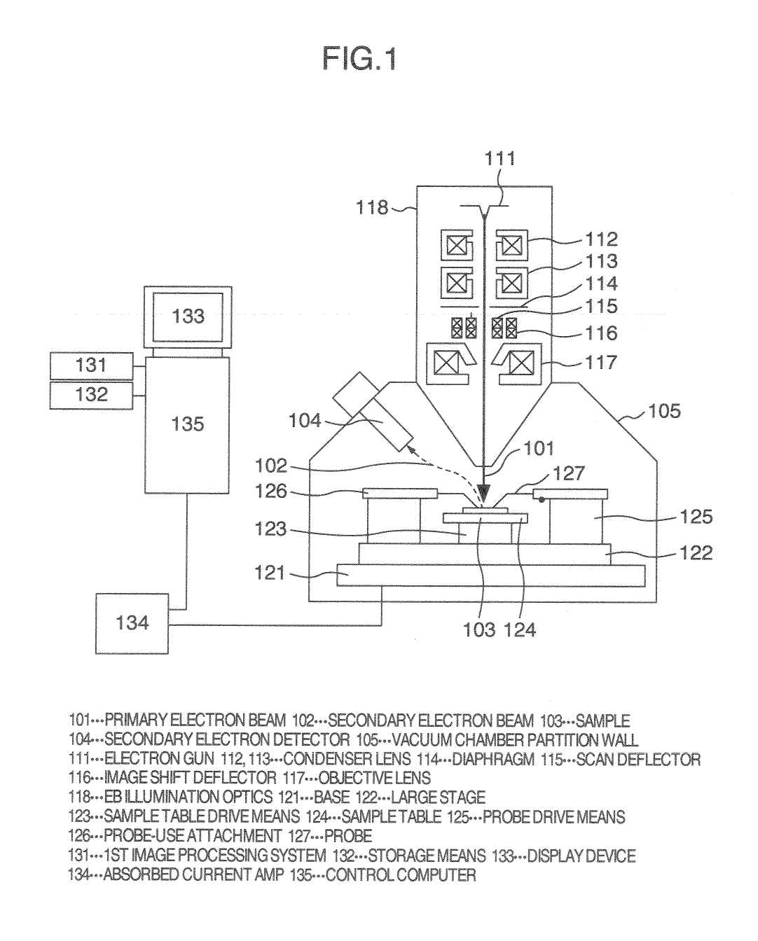

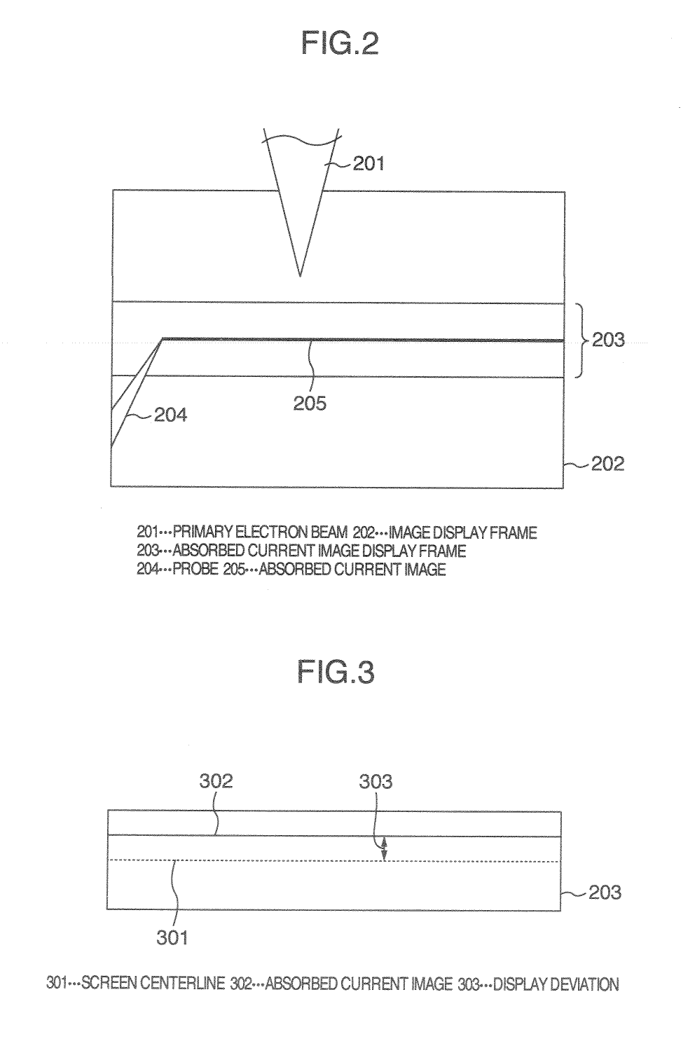

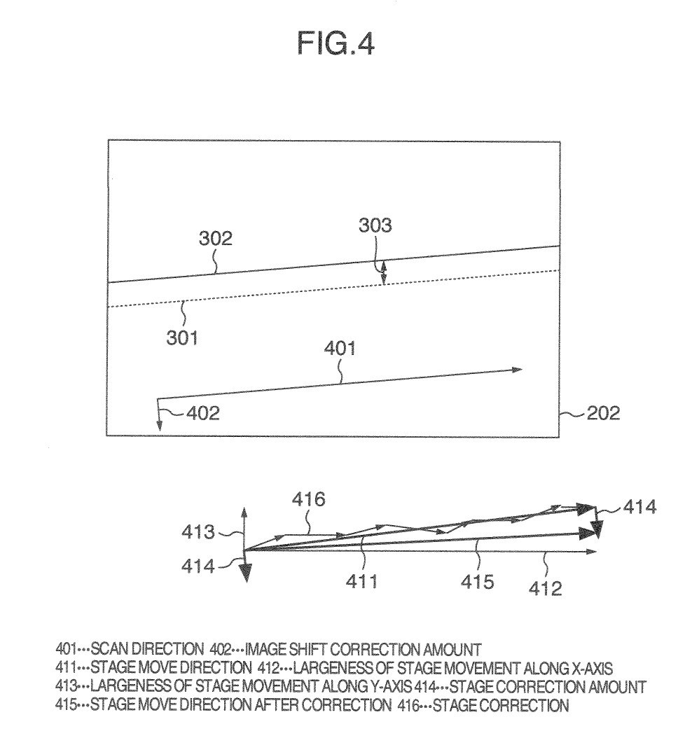

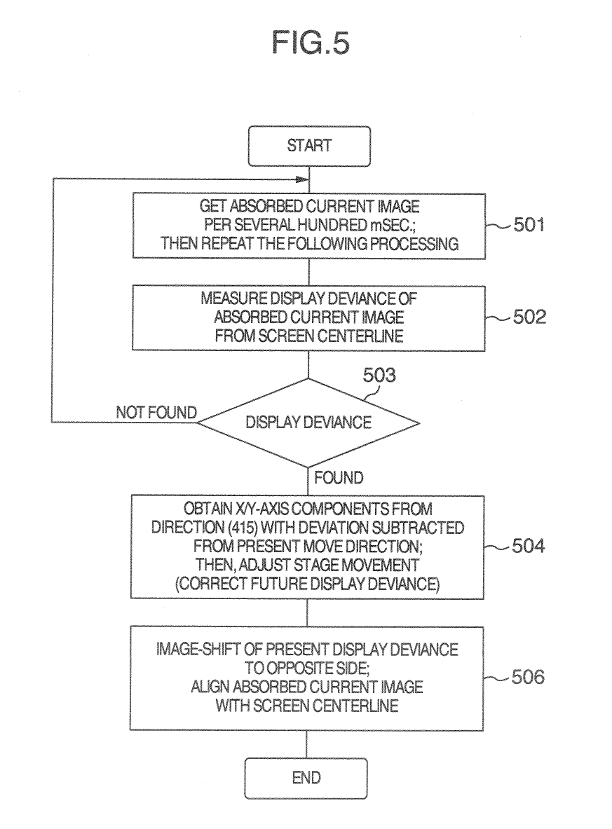

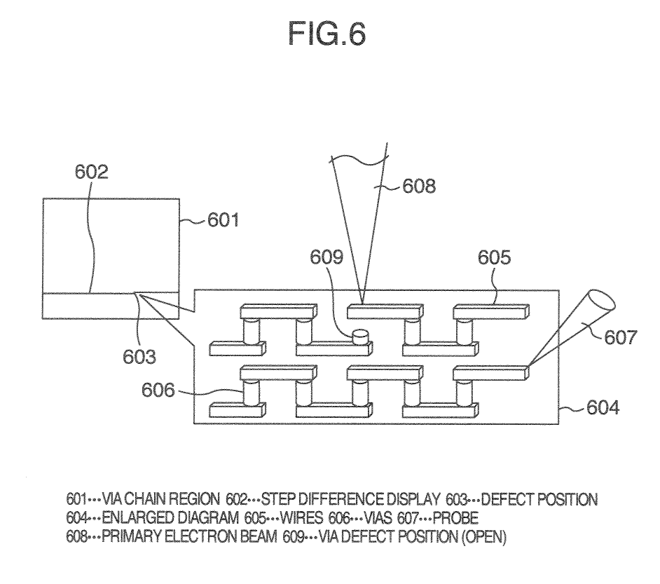

### BRIEF DESCRIPTION OF DRAWINGS

[FIG. 1] A diagram schematically showing a configuration of a semiconductor inspection apparatus.

[FIG. 2] A display diagram of an absorbed current image.

[FIG. 3] A diagram representing a deviation of absorbed current image from a center line of display frame.

[FIG. 4] A diagram indicating a correction method needed in the case of a wiring line being slanted obliquely.

[FIG. 5] A flow chart for correction.

[FIG. 6] A diagram showing a defect of a via chain.

### DESCRIPTION OF EMBODIMENTS

An embodiment of this invention will be explained with reference to the accompanying drawings below.

FIG. 1 is a diagram showing schematically a configuration of a semiconductor inspection apparatus to which one embodiment of this invention is applied.

In FIG. 1, the semiconductor inspection apparatus irradiates a primary electron beam 101 of SEM (Scanning Electron Microscope) with respect to a thin piece of sample 103 within a vacuum chamber partition wall 105. Then, a secondary electron beam 102 is detected by a secondary electron detector 104 whereby a SEM image of semiconductor device is displayed at a display device 133 through a control computer 135. This SEM image is used when bringing a probe 127 into contact with the sample 103.

Regarding an absorbed electron current image, the primary electron beam 101 is hit to the thin-piece sample 103 within the vacuum chamber partition wall 105; an electrical current absorbed into the sample 103 is amplified by an absorbed current amplifier 134 through the probe 127; the current quantity is calculated as brightness by the control computer 135; and, an absorbed current image is displayed at the display device 133. By this absorbed current image, wiring failure/defect locations are rendered apparent.

The control computer 135 uses a first image processing system 131 and a storage or “memory” means 132 plus the display device 133 to perform operation control of an entirety of the semiconductor inspection apparatus, such as switching between SEM image and absorbed current image, graphics editing of the absorbed current image, stage movement and magnification changeover.

An electron beam illumination optics system 118 permits generation of the primary electron beam 101 from an electron gun 111 by way of condenser lenses 112-113, a diaphragm 114, a scan deflector 115, an image shift deflector 116 and an objective lens 117. There is also a case where only one condenser lens is employed. The scan deflector 115 determines a scanning direction and magnification. The image shift deflector 116 modifies an image shift amount.

A stage 124 is equipped with a large stage 122 on or above a base 121, a sample table drive means 123, sample table 124, probe drive means 125, probe-use attachment 126, and probe 127.

There are several types for the probe 127: one is a probe which moves by the stage movement in synchronization therewith; another is a probe that does not move by such stage movement. There is also a probe of the type having both of these functionalities. In this embodiment, an explanation will be given using a scheme of enabling the stage to move while at the same time letting the probe be in contact with the sample. In the case of acquiring the aimed EBAC image, the type of driving the probe 127 and the stage to move in synchronization with each other is essential because of the fact that the stage is demanded to move during the needle contact, which is equivalent to a type with the probe 127 being mounted above the large stage 122. In the schematic configuration diagram, the stage of the base 121 travels in synchronization with the probe 127 whereas the sample table drive means 123 is not synchronized with the probe 127, which is used for rough approaching of the probe 127 and the sample 103.

Regarding a traveling direction of the stage and a direction of a wiring line to be inspected, it is impossible to perform end-to-end inspection if these are not the same direction. In addition, in order to judge a wiring line of the EBAC image during needle contact and also during stage movement, it is required that the scan direction and the wiring line be in parallel with each other. The reason of this is as follows: in a case where the distance of scanning from an end to the other end of the wiring line is long, part of the wire can experience data loss due to the stage being presently moving; once the data of a defective portion is lost, the defective position is no longer determinable. Adversely, if the scan direction and the wire cross together at right angles, this would result in an increase in acquisition interval corresponding to the movement. In order to make sure that there is no data acquisition failure, it becomes a parallel layout, which is less in influence of the stage movement.

In FIG. 2, after the needle contact, a primary electron beam 201 is irradiated to thereby create an absorbed current image from SEM image. Within an image display frame 202, an absorbed current image 205 is displayed by means of the primary electron beam 201 that was absorbed into the wiring line while letting a probe 204 be in contact with the wire.

Regarding how to swing the primary electron beam 201, its width may be arranged to fall within a range which permits the wire and its nearby area to be contained therein, rather than an image frame 202 of the entire display screen, in view of the fact that what is required is to visualize the wire per se. For example, scanning is applied to the inside of an absorbed current image display frame 203 with its height of ¼. The resulting scan area becomes ¼, and one-screen processing time becomes ¼. Therefore, with this scheme of utilizing image recognition of the absorbed current image, it is possible to increase the moving speed of the stage also in a following way. This results in an increase in throughput of the whole; thus, it is possible to derive a result quickly.

Upon irradiation of the primary electron beam 201 onto an inside area of the scan area, an electrical current flows in the amplifier with respect to a specific location only, which was electrically coupled to the probe 204. Accordingly, such part becomes an absorbed current image 205, which shines.

Next, the stage is driven to move toward the left side and travel in such a way that this absorbed current image 205 passes through the center of the display screen at all times, thereby making it easier to determine where a wiring failure exists.

However, in FIG. 3, an absorbed current image 302 is such that because the accurate operation capability is lost due to the backlash or the like, the absorbed current image 302 goes off from its inherently existing position on a center line 301 at the center of the display screen, resulting in occurrence of a display deviance 303. It will soon disappear from the viewing field since the absorbed current image display frame is merely 126 μm even in the case of the magnification being set to one-thousand times.

In reality, when pasting the sample to the sample table, a deviation of several degrees takes place, resulting in presence of a tilt or inclination.

For this reason, the centerline 301 of the display screen and the absorbed current image 302 are tilted obliquely as shown in FIG. 4; however, these are viewable to extend just laterally by canting a scan direction 401 by means of raster rotation.

Since there is shown here one case where the image display frame 202 has no rotation of SEM and indicates the same direction as the stage, pictorial representation is given under an assumption that the direction of the image display frame 202 is the same as the direction of the stage.

In this state, when driving the stage to move truly laterally, deviation occurs obviously; in view of this, it is necessary to move the stage also to an extent corresponding to the raster rotation. The stage's moving direction is indicated by 411. Usually the stage operates with the aid of X-axis and Y-axis; so, it operates by a vector with its movement largeness 412 along the X-axis and by a vector with its movement largeness 413 along the Y-axis. At the beginning, the stage moving direction and the scan direction are the same direction; however, this is not always right since there are inherently deviations relative to the axis of SEM and the axis of the stage. For the very reason, while the stage is moving, the absorbed current image 302 is out of the centerline 301 of the display screen, resulting generation of a display deviance 303. Here, an image shift correction amount 402 becomes necessary for correction of visual appearance or “look” of the display deviance.

Additionally, vectors on the stage side are represented by 411 to 415. In another task, this display deviation is measured automatically by acquiring an absorbed current image at time intervals of several hundreds of milliseconds.

An explanation will be given using a flowchart of FIG. 5. Although at the beginning the movement is performed while dividing it into largeness of a stage X-axis movement 412 and largeness of a stage Y-axis movement 413 in order to cause the stage to move in a stage moving direction 411, since correction of the display deviance 303 becomes necessary, vector addition of a stage correction amount 414 is performed from the present stage moving direction 401, let a stage movement 502 toward a direction of cancel-out of this display deviation 303 be the stage correction amount 414, resulting in acquisition of an amended stage moving direction 415, and then divide such moving direction into X-axis and Y-axis components, thereby forcing it to approach the correct angle.

With this, the display deviation is expected to become smaller from now, resulting in coming close to the centerline of the display screen. In addition, in order to correct the present display deviance, image shift is performed by an extent that is the same as the stage correction amount 414, thereby making it possible to display the absorbed current image within the absorbed current image display frame 203 at all times, thus enabling analysis of defect positions.

If there is a case where it runs off from the absorbed current image display frame, the stage speed is too high, which means that the image correction at the time intervals of several hundreds of milliseconds is not satisfiable. This is resolvable by setting it to a relatively lower stage speed at a system adjustment stage. This correction becomes a slower correction than the correction of only the stage that attempts to operate at the correct angle because there are image verification and communication overhead.

In short, the processing for realization of an operation at the inherently right angle consists essentially of three correction processes: stage correction (amended stage move direction 415) of a display deviance due to the image recognition, read correction of stage coordinates (stage correction 416) per elapse of 20 milliseconds, and correction by the image shift capable of amending the absorbed current image in a moment.

Acquisition of the absorbed current image is performed while at the same time moving the stage. As this is done during movement, resultant accuracy naturally drops down. In addition, since the scan mode is slow, there is no multiplication processing to be done for TV images; so, there is no delay due to such multiplication. During one-screen traveling, images corresponding to several screens are acquired, thereby letting them be an image without check failures. The image processing includes execution of subtraction and/or differentiation relative to a previous image for checking of a difference which tends to be overlooked by human eyes in order to view a difference in absorbed current more precisely. Since the interval of execution of the stage correction of a display deviance due to the image recognition differs depending upon an allowable range of the display deviance, it becomes different depending on a display magnification. In view of this, remedial action is to be taken by slowing the stage speed when the magnification becomes higher.

In the case of the sample being a via chain, which is viewed as an oblong figure unlike the wiring line, this is constituted from multiple arrays each having a linear array of laterally wired ones in a similar manner to the raster of a display screen. Ad extremum, the contrast is different between upper and lower portions of a defect position. Accordingly, the defect position is determinable when viewing just laterally the position at which a defect exists. This makes it possible to accurately find out defect positions by this method in a similar way to the wiring line.

A defect example of the via chain is shown in FIG. 6. There is a via chain region 601. When displaying an EBAC image, a step-like difference is displayed (602) at a defect position 603 in some cases. An enlarged diagram of the defect position is indicated by 604.

The via chain is structured from wiring lines 605 and vias 606. When bringing a probe 607 into contact with an edge and then performing the scanning of a primary electron beam 608, the brightness varies as shown by 602 between an electrical current-flowing portion and a no-current-flowing portion, thereby making a defect position determinable.

When the primary electron beam 608 is swung to the left-hand side of a via defect position 609, no current flows into the probe 607; when it is swung to the right side, a current flows. By increasing the acceleration voltage, an electrical current which was absorbed into those including a lower wiring line. This permits determination of establishment of electrical connection. With the step-like difference display 602 as a boundary on display image, its upside is dark whereas downside is bright. Although the enlarged picture is represented in the form of two stages, multiple ones exist repeatedly within the whole via chain region 601, all of which are coupled together.

Even in the case of this type of via chain, an accurate defect position becomes apparent by inspecting laterally straightly a portion performing the step difference display 602.

When driving the stage to move just laterally in this way, it is possible to reach the defect position more apparently by forcing stage to reciprocate a plurality of times while changing the magnification ratio and/or modifying the acceleration voltage of the primary electron beam. By changing the magnification ratio to a higher level, a defect position that has not been viewable until now is enlarged and, obviously, becomes more apparent.

Additionally, an increase in the acceleration voltage results in the primary electron beam reaching a lower layer of wiring lines, thereby permitting determination of defect positions, such as short-circuiting or the like, in a layer that has ever been invisible. However, initially applying a high acceleration voltage leads to an increase in damage to the sample. It is important to increase the acceleration voltage gradually in a stepping fashion in order to avoid exertion of influence by irradiation of the primary electron beam also.

Although an apparatus with its sample table per se being designed to rotate is able to cope with the just-lateral movement by moving only the X-axis after having performed rotation of a designated angle, an apparatus with the lack of such sample table rotatability is arranged so that the table is moved just laterally or horizontally by moving two axes of X-axis and Y-axis. As the cause of the lack of just-lateral movement, there are errors due to the backlash, the height of a ball screw thread, and two-axis design. There is also a stage using piezoelectric elements with no backlash. However, it is assumed here to employ the type using a ball screw.

Although the stage movement is such that attention is paid to how it can stop at the right position, i.e., the stopping accuracy, those are rarely found which seek the right moving direction like the illustrative embodiment apparatus. In other words, since importance is given to the quest for accurate and rapid stoppage at a designated position, the trace of a stage movement until today has drawn a significantly curved line.

Regarding the backlash, the maximum backlash amount is determinable; however, a handling scheme is changed depending on a present value of the backlash amount. Considering the backlash only, there are three major patterns: at the start-up, at the time of the same direction, and at the time of the reverse direction. At the startup, the backlash amount is not exactly determinable because it depends on how the stage has been moved before the startup. It is also thinkable to expect a user to have a consciousness of moving to which one of available directions and perform, without fail, needle contacting after having removed the backlash and then move it. Unfortunately, this approach has a drawback of the difficulty in determining a removal direction since the Y-axis direction is at or near the zero degree—in this case only, an operation is performed under an assumption that the backlash amount is indefinable.

To be more precise, the moving direction is determined; so, image shift-based correction is performed based on an absorbed current image while suppressing the speed of the stage. In this regard, however, the correction of the stage moving direction is not performed because a cursory change of the stage move direction for prompt compensation of a difference of the stage's direction results in the movement angle becoming a totally different angle. In the case of moving it in the same direction, there is no backlash; so, this may not be taken into consideration.

In the case of moving in the reverse direction, the stage does not move by a degree corresponding to the maximum backlash. This makes it possible to travel up to a portion close to the maximum backlash while ignoring a movement-wanted angle. It was possible to take countermeasure by gradually moving from there and performing the image shift-aided correction on the basis of an absorbed current image.

Although in some cases the absorbed current image wobbles up and down in a certain cycle in a way depending on the height of a ball screw thread, it was possible to cope with it by performing stage angle correction and image shift correction based on the absorbed current image. In this case, the stage angle correction is also performed because of the lack of any determinability as to whether it was caused by the ball screw height or by the presence of a difference of the true stage move angle.

Regarding the two-axis error, the designated angle is divided into sine and cosine components, respective ones of which are set to X-axis and Y-axis. However, since the sample table moves almost along the X-axis, the Y-axis component becomes a value nearly equal to zero. In addition, the designated value for stage movement has a drawback: it is impossible to accurately designate it in a manner of identifying what number of digits after decimal point. While using the sine value to set to the Y-axis a value nearest thereto with the minimum unit of Y-axis and also setting a value obtained from the cosine value to the X-axis in a similar way, when the angle is recalculated from the calculated X-axis and Y-axis, a large error takes place in the process of recalculating the angle from these computed X- and Y-axes due to the fact that the value of Y-axis is small and thus the error is large. As a remedy for this, a value of X-axis which becomes the right angle is obtained based on the value of Y-axis since a small value of Y-axis is not modified in any way whereby it was possible to take countermeasure for the right angle. By feedbacking this angle and correcting again the actual moving amount with 20 milliseconds being as a unit, it was possible to move while keeping the right angle.

When pasting a sample to the sample table resulting in wiring lines extending vertically, countermeasure is taken by tilting the raster rotation by 90 degrees since the operation in this case is for lateral movement. By outing while deflecting the raster by 90 degrees, the wire also is viewable to extend laterally, which is expected to travel just laterally or horizontally.

In the case of wires running in vertical and lateral directions, it is also possible to rotate it by 90 degrees in an automated way. In this respect, however, higher priority is given to the just lateral direction in the case of a “T”-like shape. Since automated execution of the raster rotation along the wires in this way would result in the lack of an ability to identify where a present point exists within the overall area. To avoid this, a currently approaching direction is shown along with an entire bird's-eye view, thereby enabling judgment of a presently indicated position on the display screen. Additionally, by showing several defect positions in the entire bird's-eye view, it is possible to move at a designated defect position—this is convenient.

A defect position has image-associated information. By arranging this information to contain therein each stage position, image shift movement amount, raster rotation amount and magnification and also by performing, after the movement, recognition of a positional deviation of an image which has been regarded as a present image, it is possible to recreate the defect position more precisely.

As the final result, it is required to perform marking of the defective positions detected. Although what can be done here is merely to add marks onto the display screen, it is also possible, for example, to use the probe to add marks to the sample.

It is very important to report these defect positions to another apparatus. Generally, there is a CAD navigation which marks defect positions or else by use of CAD data obtained when fabricating semiconductor devices. By additionally sending to this CAD navigation the probe position and the defect positions, the convenience increases.

As for the probe position, there is no data during fabrication of semiconductor devices; so, no data is available on the ordinary CAD navigation side. By transferring to CAD navigation the position of a needle-touched probe, it is possible by investigation of those wires existing at a nearby position to highlight an equipotential level of such wire. If it is possible to move the probe using the CAD navigation, it becomes possible to achieve rough approaching of needle contact by selecting a wire.

### REFERENCE SIGNS LIST

101 Primary Electron Beam

102 Secondary Electron Beam

103 Sample

104 Secondary Electron Detector

105 Vacuum Chamber Partition Wall

110 Electron Beam Illumination Optics System

111 Electron Gun

112 Condenser Lens 1

113 Condenser Lens 2

114 Diaphragm

115 Scan Deflector

116 Image Shift Deflector

117 Objective Lens

121 Base

122 Large Stage

123 Sample Table Drive Means

124 Sample Table

125 Probe Drive Means

126 Probe-Use Attachment

127, 204, 607 Probe

128 Electrical Characteristics Measuring Equipment

131 First Image Processing System

132 Storage Means

133 Display Device

134 Absorbed Current Amp

135 Control Computer

201 Primary Electron Beam

202 Image Display Frame

203 Absorbed Current Image Display Frame

205, 302 Absorbed Current Image

301 Center Line of Screen

303 Display Deviation

401 Scan Direction

402 Image Shift Correction Amount

411 Stage Move Direction

412 Movement of Stage X-axis

413 Movement of Stage Y-axis

414 Stage Correction Amount

415 Stage Move Direction After Correction

416 Stage Correction

601 Via Chain Region

602 Step-Like Difference Display

603 Defect Position

604 Enlarged Diagram

605 Wire

606 Via

608 Primary Electron Beam

609 Via Defect Position (Open)

1. A semiconductor inspection apparatus comprising:
a sample table capable of mounting a sample thereon;
a stage capable of moving said sample table;
an electron beam illumination optics system capable of irradiating an electron beam;
a detector capable of detecting secondary electrons to be generated from the sample;
a plurality of probes capable of getting contact with said sample;
a measurement device for measuring electrical currents flowing in said plurality of probes;
an amplifier to which is input a signal from said measurement device; and
an image device for outputting an absorbed current image based on a signal from said amplifier and a signal depending upon scanning of said electron beam illumination optics system, wherein
an electrical current is amplified which flows into a probe through an intra-sample wiring line due to irradiation of the electron beam in a state that the probe is in contact with a wiring line of the sample or a pad thereof, wherein said image device acquires an absorbed current image while representing the wiring line of semiconductor by brightness, and wherein said stage performs stage movement in the state that the probe is in contact to thereby acquire the absorbed current image during movement.

2. The semiconductor inspection apparatus according to claim 1, wherein said electron beam is scanned in a direction along said wiring line in such a manner that an increase in the absorbed current is displayed within a display frame having a prespecified width on a display surface of said display device and wherein the stage movement is performed in such a way that an image of the wiring line is within the prespecified width.

3. The semiconductor inspection apparatus according to claim 2, wherein said stage defines moving velocities of X-axis and Y-axis of the stage so as to travel in the wiring line's direction and wherein said apparatus further comprises a deflector which reads stage coordinates at predetermined time intervals for correcting the stage movement direction and which modifies the electron beam in such a way that the image of the wiring line is displayed in a center direction within said display frame.

4. The semiconductor inspection apparatus according to claim 1, wherein an acceleration voltage of the electron beam illumination optics system is varied every time the stage moves to an end of the wiring line of the sample, thereby acquiring an absorbed current image of a wiring line at a different depth.

5. The semiconductor inspection apparatus according to claim 1, wherein a magnification ratio of the electron beam illumination optics system at a position with possibility of being a defect position is increased to thereby make the defect position more apparent.

6. The semiconductor inspection apparatus according to claim 1, wherein a defect position is obtained based on the absorbed current image and wherein marking is applied to this defect position using the probe.

7. A semiconductor inspection method using a semiconductor inspection apparatus having a sample table capable of mounting a sample thereon, a stage capable of moving said sample table, an electron beam illumination optics system capable of irradiating an electron beam, a detector capable of detecting secondary electrons to be generated from the sample, a plurality of probes capable of getting contact with said sample, a measurement device for measuring electrical currents flowing in said plurality of probes, an amplifier to which is input a signal from said measurement device, and an image device for outputting an absorbed current image based on a signal from said amplifier and a signal depending upon scanning of said electron beam illumination optics system, wherein said method comprises the steps of:
amplifying an electrical current flowing into a probe through an intra-sample wiring line due to irradiation of the electron beam in a state that the probe is in contact with the wiring line of the sample or a pad thereof;
causing said image device to acquire an absorbed current image while representing the wiring line of semiconductor by brightness; and
causing said stage to perform stage movement in the state that the probe is in contact to thereby acquire the absorbed current image during movement.
